(19) United States
(12) Patent Application Publication
(10) Pub. No.: US 2017/0155027 A1
(43) Pub. Date: Jun. 1, 2017

(54) THERMOELECTRIC GENERATING SYSTEM

(71) Applicant: Hyundai Motor Company, Seoul (KR)

(72) Inventors: Jin Woo Kwak, Gyeongsan (KR); In Woong Lyo, Suwon (KR); Kyong Hwa Song, Seoul (KR); Han Saem Lee, Seoul (KR); Byung Wook Kim, Seongnam (KR); Hong Kil Baek, Seoul (KR); Seung Woo Lee, Seoul (KR); Tae Won Lim, Seoul (KR); Kwang Hee Nam, Ansan (KR); Sang Soo Min, Bucheon (KR)

(21) Appl. No.: 15/209,583

(22) Filed: Jul. 13, 2016

(30) Foreign Application Priority Data
Nov. 26, 2015 (KR) 10-2015-0166507

(51) Int. Cl. H01L 35/30; H01L 35/32

(52) U.S. Cl. CPC H01L 35/30; H01L 35/32

(57) ABSTRACT

A thermoelectric generating system is provided. The system includes one or more thermoelectric modules that are mounted on a top surface of a heat source part and a cooling part that is disposed over the thermoelectric modules. A pressurizing device is configured to pressurize the thermoelectric modules and the cooling part toward the heat source part and a cover is installed to cover an upper portion of the pressurizing device.

### CROSS-REFERENCE TO RELATED APPLICATION

This application is based on and claims the benefit of priority to Korean Patent Application No. 10-2015-0166507, filed on Nov. 26, 2015 in the Korean Intellectual Property Office, the disclosure of which is incorporated herein in its entirety by reference.

### TECHNICAL FIELD

The present disclosure relates to a thermoelectric generating system, and more particularly, to a thermoelectric generating system that implements output improvement based on an acquisition of a temperature difference between a hot side and a cold side of the system by preventing thermal loss in a thermoelectric module while preventing damage to the thermoelectric module due to a high temperature vibration by firmly mounting the thermoelectric module to the hot side.

### BACKGROUND

As is well known, a thermoelectric generating system is configured to generate electricity by a thermoelectric module, and the thermoelectric module may generate electricity using an effect in which thermal electromotive force is generated by a temperature difference of both sides thereof. The thermoelectric generating system according to the related art is configured to generally mount one surface of the thermoelectric module onto an exhaust pipe of a vehicle to increase electricity generation amount thereof, and to mount a water cooling system onto the other surface of the thermoelectric module to secure a temperature difference thereof.

Accordingly, since the thermoelectric generating system according to the related art includes the thermoelectric module mounted onto the exhaust pipe of a high temperature (e.g., 400° C. or greater) in a structure which is opened or exposed to the outside, the thermoelectric generating system is repetitively exposed to the high temperature and the low temperature. As a result, since heavy heat loss occurs, it may be difficult to secure a temperature difference between a hot side and a cold side, and an adhesion part of the thermoelectric module, a thermoelectric element, and the like may be damaged by a thermal shock. Therefore, the system of the related art, has a disadvantage in that durability of the thermoelectric module is decreased. Further, since the thermoelectric generating system according to the related art is mounted onto an exhaust system such as the exhaust pipe, an exhaust muffler, or the like, the temperature difference between the hot side and the cold side is not sufficiently secured. As a result, there is a limit that a high output current may not be obtained.

### SUMMARY

The present disclosure provides a thermoelectric generating system capable of preventing damage to a thermoelectric module while sufficiently securing a temperature difference between a cold side and a hot side by mounting the thermoelectric module to a heat source part of a high temperature using a cover to minimize heat loss to the outside.

Particularly, since the thermoelectric module may be mounted onto an engine side, which is a heat source of a high temperature higher than an exhaust system, using the cover, heat of higher temperature may be used. Accordingly, an aspect of the present disclosure provides a thermoelectric generating system capable of obtaining a high output current by maximizing a temperature difference between a hot side and a cold side.

According to an exemplary embodiment of the present disclosure, a thermoelectric generating system may include one or more thermoelectric modules mounted on a top surface of a heat source part; a cooling part disposed over (e.g., covering) the thermoelectric modules; a pressurizing device configured to pressurize the thermoelectric modules and the cooling part toward the heat source part; and a cover installed to cover an upper portion of the pressurizing device.

The cooling part may include a cooling jacket through which a cooling fluid may pass. Additionally, the thermoelectric generating system may further include an insulation configured to be filled around the thermoelectric modules. The pressurizing device may be a pressurizing mat that pressurizes the cooling part to allow the thermoelectric modules to be closely adhered to the heat source part. The pressurizing mat may have a predetermined compression ratio, and may be formed of a material of which surface pressure is adjustable based on the compression ratio.

Further, the pressurizing mat may be a complex mat having a ceramic fiber and a layered silicate material. The pressurizing device may be a metal mesh. In addition, the cover may have a side wall that surrounds side surfaces of the thermoelectric modules, the cooling part, and the pressurizing device, a coupling flange may be formed at an edge of a lower end of the side wall of the cover, and the coupling flange of the cover may be coupled to an edge of the heat source part. The cover may be configured in a plate shape, and edges of the cover may be coupled to the heat source part by fasteners.

According to another exemplary embodiment of the present disclosure, a thermoelectric generating system may include one or more thermoelectric modules seated on a top surface of a heat source part; a cooling part disposed over the thermoelectric modules; a damping device configured to provide damping property to the thermoelectric modules; and a cover installed to cover an upper portion of the damping device.

The damping device may be one or more damping springs interposed between the cooling part and the cover. The cooling part may include a cooling jacket through which a cooling fluid may pass. The cooling jacket may include housing grooves in which the damping springs may be housed. Inserting grooves into which the thermoelectric modules are inserted may be formed in the top surface of the heat source part. The thermoelectric generating system may further include an insulation configured to be filled around the thermoelectric modules

### BRIEF DESCRIPTION OF THE DRAWINGS

The above and other objects, features and advantages of the present disclosure will be more apparent from the following detailed description taken in conjunction with the accompanying drawings

FIG. 1 is a diagram illustrating a thermoelectric generating system according to a first exemplary embodiment of the present disclosure;

FIG. 2 is a diagram illustrating a thermoelectric generating system according to a second exemplary embodiment of the present disclosure;

FIG. 3 is a plan view illustrated along line A-A of FIG. 2 according to the second exemplary embodiment of the present disclosure;

FIG. 4 is a diagram illustrating a thermoelectric generating system according to a third exemplary embodiment of the present disclosure;

FIG. 5 is a diagram illustrating a thermoelectric generating system according to a fourth exemplary embodiment of the present disclosure; and

FIG. 6 is a diagram illustrating a thermoelectric generating system according to a fifth exemplary embodiment of the present disclosure.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, combustion, plug-in hybrid electric vehicles, hydrogen-powered vehicles and other alternative fuel vehicles (e.g. fuels derived from resources other than petroleum).

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor. The memory is configured to store the modules and the processor is specifically configured to execute said modules to perform one or more processes which are described further below.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/of” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

Hereinafter, exemplary embodiments of the present disclosure will be described in detail with reference to the accompanying drawings. For reference, sizes of components, thicknesses of lines, and the like which are shown in the drawings referenced for describing the present disclosure may be slightly exaggerated for convenience of understand. Further, since the terminologies used to describe the present disclosure are defined in consideration of the functions in the present disclosure, they may be construed in different ways depending on a user, an intention of an operator, practices, and the like. Therefore, the definition of the terminologies should be construed based on the contents throughout the specification.

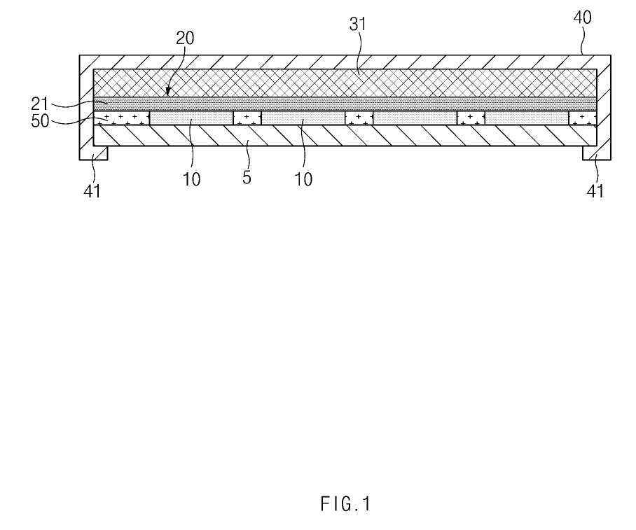

FIG. 1 is a diagram illustrating a thermoelectric generating system according to a first exemplary embodiment of the present disclosure. Referring to FIG. 1, the thermoelectric generating system according to the first exemplary embodiment of the present disclosure may include one or more thermoelectric modules 10 mounted on a top surface of a heat source part 5 such as an engine of a vehicle, or the like, a cooling part 20 disposed over (e.g., on top of, covering, etc.) the thermoelectric modules 10, a pressurizing device configured to pressurize the thermoelectric modules 10 and the cooling part 20 toward the heat source part 5, and a cover 40 installed to cover (e.g., enclose) an upper portion of the pressurizing device.

The thermoelectric module 10 may have a semiconductor part having a pair of semiconductor elements (e.g., a p-type semiconductor element and an n-type semiconductor element) of which polarities are opposite to each other, and an electrode part that electrically connects the semiconductor parts. Since the thermoelectric module 10 may be mounted on the top surface of the heat source part 5, the thermoelectric module 10 may be configured to receive heat of a substantially high temperature (e.g., about 400° C. or greater) from the heat source part 5, thereby making it possible to configure a hot side. Since the cooling part 20 may be installed over the thermoelectric module 10, the cooling part 20 may be configured to cool an upper portion of the thermoelectric module 10, thereby making it possible to configure a cold side at an upper side of the thermoelectric module 10.

According to an exemplary embodiment, the cooling part 20 may include a cooling jacket 21 having a cooling passage through which a cooling medium may pass. Accordingly, since a lower portion of the thermoelectric module 10 may be configured as the hot side by the heat source part 5, and the upper portion of the thermoelectric module 10 may be configured as the cold side by the cooling part 20, the thermoelectric module 10 may be configured to perform thermoelectric generation using a temperature difference between the hot side and the cold side. The pressurizing device may be configured to pressurize the thermoelectric module 10 and the cooling part 20 toward the heat source part 5, the thermoelectric module 10 and the cooling part 20 may be more firmly installed to be adjacent to the heat source part 5. Accordingly, there is an advantage that it may be possible to effectively prevent the thermoelectric module 10 from being damaged by vibration, or the like.

According to an exemplary embodiment, the pressurizing device may be configured of a pressurizing mat 31, and the pressurizing mat 31 may be disposed on a top surface of the cooling part 20, thereby making it possible to pressurize the cooling part 20 and the thermoelectric module 10 toward the heat source part 5. Accordingly, the thermoelectric module 10 may be closely adhered (e.g., abut) to the heat source part 5, thereby making it possible to maintain firm mounting property of the cooling part 20 and the thermoelectric module 10.

The pressurizing mat 31 may have a predetermined compression ratio, and surface pressure of the pressurizing mat 31 may be adjusted based on the compression ratio of the pressurizing mat 31, thereby making it possible to secure appropriate pressurizing performance for the thermoelectric module 10. The pressurizing mat 31 may be formed of a complex mat configured by mixing a ceramic fiber and a layered silicate material. In addition, an insulation (e.g., an insulation material) such as a glass wool, or the like may be densely filled around the thermoelectric module 10. Accordingly, it may be possible to prevent a variety of components of the thermoelectric module 10 from being separated to the outside and it may be possible to more effectively prevent heat loss to the outside. As a result, the temperature difference between the cold side and the hot side of the thermoelectric module 10 may be sufficiently secured.

Further, the insulation 50 may be filled between the thermoelectric module 50 and the cooling part 20 as well as around the thermoelectric module 10, and may also be filled between the cooling part 20 and the pressurizing mat 31. The cover 40 may be installed to cover the upper portion of the pressurizing mat 31, thereby making it possible to stably protect the thermoelectric modules 10, the cooling part 20, the pressurizing mat 31, and the like from external physical and thermal influences. The cover 40 may have a side wall that covers side surfaces of the thermoelectric modules 10, the cooling part 20, the pressurizing mat 31, and the like. Accordingly, since the cover 40 may be coupled to the heat source part 5 while surrounding the thermoelectric modules 10, the cooling part 20, the pressurizing mat 31, and the like, the cover 40 may encapsulate and protect the thermoelectric modules 10, the cooling part 20, and the pressurizing mat 31.

In addition, a coupling flange 41 may be formed at an edge of a lower end of the side wall of the cover 40, and the coupling flange 41 of the cover 40 may be coupled to an edge of the heat source part 5 by welding, or the like. When the cooling part 20 and the thermoelectric modules 10 are appropriately pressurized by the pressurizing mat 31, since the cover 40 may be coupled to the heat source part 5 to cover the upper portion of the pressurizing mat 31, the thermoelectric modules 10, the cooling part 20, and the like may be more firmly mounted onto the heat source part 5.

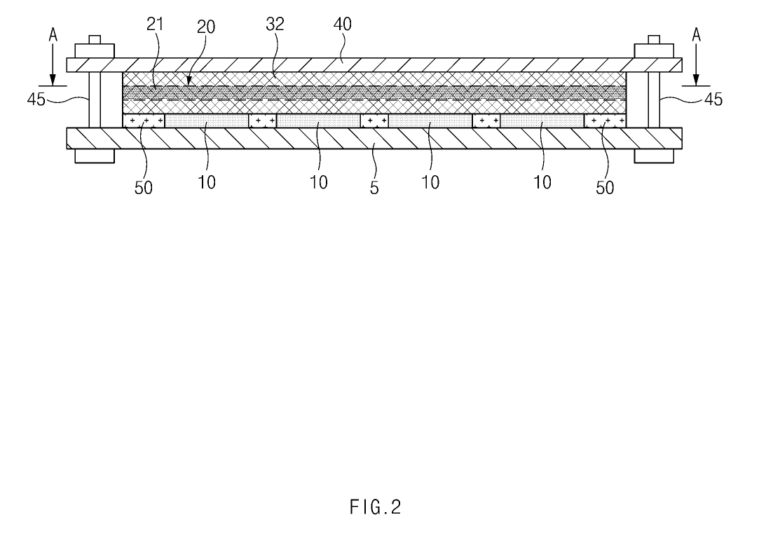

FIG. 2 is a diagram illustrating a thermoelectric generating system according to a second exemplary embodiment of the present disclosure. Referring to FIG. 2, the pressurizing device may be comprised of a metal mesh 32 having both damping property and pressurizing property. The metal mesh 32 may have a predetermined compression ratio similarly to the pressurizing mat 31, and surface pressure of the metal mesh 32 may be adjusted based on the compression ratio of the metal mesh 32, thereby making it possible to secure appropriate pressurizing performance for the thermoelectric modules 10. Further, since the metal mesh 32 has the damping property, the metal mesh 32 may perform an appropriate damping function for a thermal expansion, thereby making it possible to also more effectively prevent damage to the thermoelectric modules 10.

According to the second exemplary embodiment of the present disclosure, the cover 40 may be formed in a plate structure, and the edge of the cover 40 may be coupled to the heat source part 5 by one or more fasteners 45. The fasteners 45 may be a bolt, a stud integrally protruding from the top surface of the heat source part 5, or a similar type of fastening mechanism. Accordingly, a plurality of fasteners 45 may be fastened to penetrate through the cover 40 and the heat source part 5, thereby making it possible to more firmly couple the cover 40 to the heat source part 5.

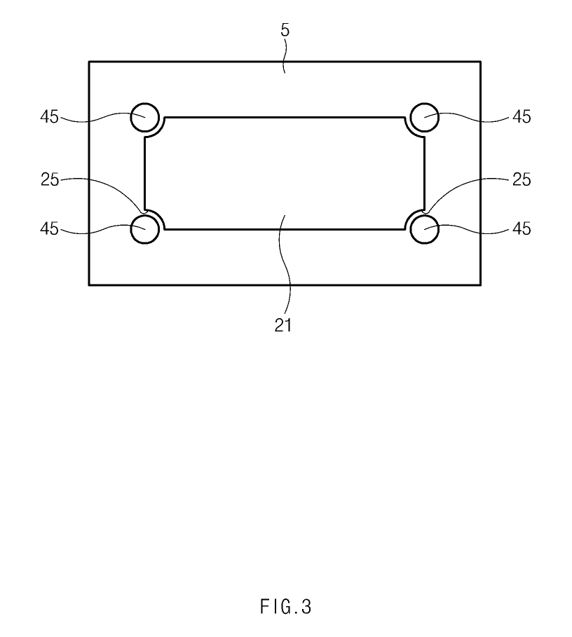

Meanwhile, as illustrated in FIG. 3, edges (e.g., corner portions) of the cooling jacket 21 of the cooling part 20 may include a plurality of groove parts 25 through which the fasteners 45 may pass. In other words, the groove parts may be formed on the cooling jacket 21 to accommodate the fasteners 45, which causes a mounting structure of the cooling jacket 21 to be more firm, thereby making it possible to surely prevent the cooling jacket 21 from being separated to the outside.

Accordingly, the second exemplary embodiment of the present disclosure is configured in a structure in which the cover 40 may be coupled to the heat source part 5 by the fasteners 45. The second exemplary embodiment may reduce a contact area between the cover 40 and the heat source part 5 compared to the first exemplary embodiment as described above (e.g., a structure in which the coupling flange 41 of the cover 40 is coupled to the edge of the heat source part 5) to minimize heat of the heat source part 5 transferred to the cover 40, thereby making it possible to minimize heat loss. Since other configurations are similar to or the same as those of the first exemplary embodiment described above, a detailed description thereof will be omitted.

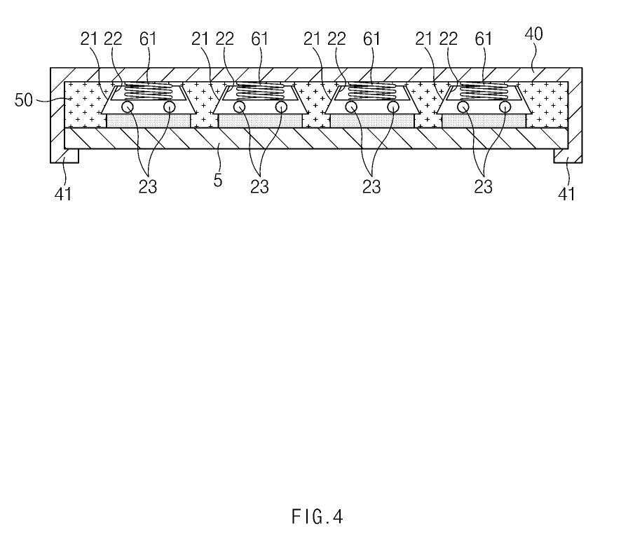

FIG. 4 is a diagram illustrating a thermoelectric generating system according to a third exemplary embodiment of the present disclosure. Referring to FIG. 4, the thermoelectric generating system according to the third exemplary embodiment of the present disclosure may include one or more thermoelectric modules 10 mounted on a top surface of a heat source part 5 such as an engine of a vehicle, or the like, a cooling part 20 disposed over the thermoelectric modules 10, a damping device configured to provide damping property to the thermoelectric modules 10, and a cover 40 installed to cover an upper portion of the damping device.

The cooling part 20 may include one or more cooling jackets 21, and cooling passages 23 through which a cooling medium passes may be formed in the cooling jackets 21. In addition, the cooling jackets 21 may be comprised of the number corresponding to the number of thermoelectric modules 10 (e.g., the number of cooling jackets 21 and thermoelectric modules 10 may correspond). Accordingly, each of the cooling jackets 21 may be separately disposed on a top surface of each of the thermoelectric modules 10. Further, the damping device may include one or more damping springs 61, and the damping springs 61 may be disposed on the cooling jackets 21, to vertically provide damping property to the cooling jackets 21 and the thermoelectric modules 10. Accordingly, it may be possible to prevent the thermoelectric modules 10, the cooling jackets 21, and the like from being damaged by thermal influence such as thermal expansion, or the like.

Meanwhile, a housing groove 22 configured to accommodate the damping spring 61 may be formed on each of the cooling jackets 21. As a result, it may be possible to prevent the damping spring 61 from being separated to the outside, and since the damping spring 61 is less vulnerable to the thermal influence of the heat source part 5, it may be possible to prevent characteristics such as an elastic modulus, or the like from changing Additionally, a coupling flange 41 of the cover 40 may be coupled to the edge of the heat source part 5 by welding, or the like similarly to the first exemplary embodiment described above. Since other configurations are similar to or the same as those of the first and second exemplary embodiments described above, a detailed description thereof will be omitted.

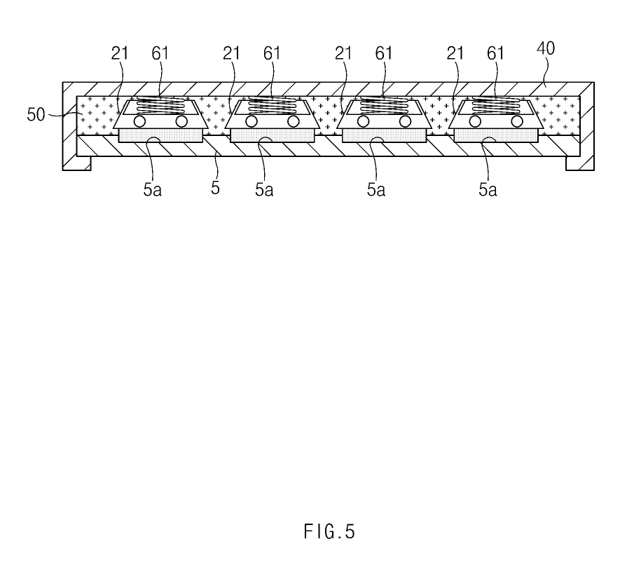

FIG. 5 is a diagram illustrating a thermoelectric generating system according to a fourth exemplary embodiment of the present disclosure. Referring to FIG. 5, inserting grooves 5a into which one or more thermoelectric modules 10 are separately inserted may be formed in the top surface of the heat source part 5. Accordingly, since the thermoelectric modules 10 may be more firmly and stably mounted onto the top surface of the heat source part 5, the separation of the thermoelectric modules 10, or the like may be prevented during an assembly of the thermoelectric modules 10 or after the thermoelectric modules 10 are mounted. Since other configurations are similar to or the same as those of the first, second, and third exemplary embodiments described above, a detailed description thereof will be omitted.

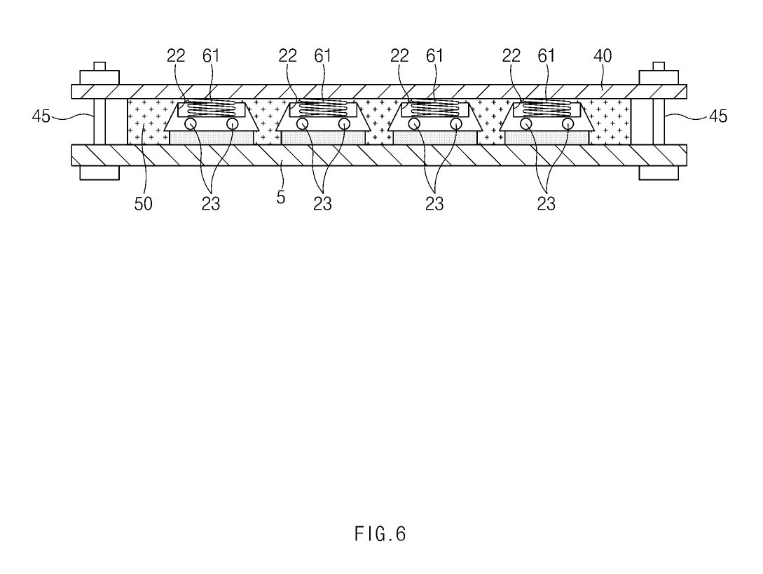

FIG. 6 is a diagram illustrating a thermoelectric generating system according to a fifth exemplary embodiment of the present disclosure. Referring to FIG. 6, the thermoelectric generating system has a structure in which the thermoelectric generating system may include the damping device according to the third exemplary embodiment (see FIG. 4), and the cover 40 may be coupled to the heat source part 5 by the fasteners 45 according to the second exemplary embodiment (see FIG. 2). Since other configurations are similar to or the same as those of the first, second, and third exemplary embodiments described above, a detailed description thereof will be omitted.

As described above, according to the exemplary embodiments of the present disclosure, the damage to the thermoelectric module may be prevented while sufficiently securing the temperature difference between the cold side and the hot side by mounting the thermoelectric module to the heat source part of the high temperature using the cover to minimize the heat loss to the outside. Particularly, since the thermoelectric module may be more easily mounted onto the engine side, which is the heat source of the high temperature higher than the exhaust system, using the cover, heat of higher temperature may be used, thereby making it possible to obtain the high output current by maximizing the temperature difference between the hot side and the cold side.

Hereinabove, although the present disclosure has been described with reference to exemplary embodiments and the accompanying drawings, the present disclosure is not limited thereto, but may be variously modified and altered by those skilled in the art to which the present disclosure pertains without departing from the spirit and scope of the present disclosure claimed in the following claims.

What is claimed is:

1. A thermoelectric generating system, comprising:
one or more thermoelectric modules mounted on a top surface of a heat source part;
a cooling part disposed over the thermoelectric modules;
a pressurizing device configured to pressurize the thermoelectric modules and the cooling part toward the heat source part; and
a cover installed to cover an upper portion of the pressurizing device.

2. The thermoelectric generating system according to claim 1, further comprising:
an insulation configured to be filled around the thermoelectric modules.

3. The thermoelectric generating system according to claim 1, wherein the pressurizing device is a pressurizing mat configured to pressurize the cooling part to allow the thermoelectric modules to adhere to the heat source part.

4. The thermoelectric generating system according to claim 3, wherein the pressurizing mat has a predetermined compression ratio, and is formed of a material of which surface pressure is adjustable based on the compression ratio.

5. The thermoelectric generating system according to claim 3, wherein the pressurizing mat is a complex mat having a ceramic fiber and a layered silicate material.

6. The thermoelectric generating system according to claim 1, wherein the pressurizing device is a metal mesh.

7. The thermoelectric generating system according to claim 1, wherein the cover has a side wall that surrounds side surfaces of the thermoelectric modules, the cooling part, and the pressurizing device, a coupling flange is formed at an edge of a lower end of the side wall of the cover, and the coupling flange of the cover is coupled to an edge of the heat source part.

8. The thermoelectric generating system according to claim 1, wherein the cover is configured in a plate shape, and edges of the cover are coupled to the heat source part by fasteners.

9. A thermoelectric generating system, comprising:
one or more thermoelectric modules seated on a top surface of a heat source part;
a cooling part disposed over the thermoelectric modules;
a damping device configured to provide damping property to the thermoelectric modules; and
a cover installed to cover an upper portion of the damping device.

10. The thermoelectric generating system according to claim 9, wherein the damping device is one or more damping springs interposed between the cooling part and the cover.

11. The thermoelectric generating system according to claim 10, wherein the cooling part includes a cooling jacket through which a cooling fluid passes.

12. The thermoelectric generating system according to claim 11, wherein the cooling jacket includes housing grooves in which the damping springs are accommodated.

13. The thermoelectric generating system according to claim 12, wherein inserting grooves into which the thermoelectric modules are inserted are formed in the top surface of the heat source part

14. The thermoelectric generating system according to claim 9, further comprising:
an insulation configured to be filled around the thermoelectric modules.
